(19) United States
(12) Patent Application Publication
(10) Pub. No.: US 2008/0007924 A1
(43) Pub. Date: Jan. 10, 2008

(54) Card adaptor device

(75) Inventor: Chien-Yuan Chen, Banchiau City (TW)

Correspondence Address: TROXELL LAW OFFICE PLLC;SUITE 1404, 5205 LEESBURG PIKE, FALLS CHURCH, VA, 22041, US

(73) Assignees: Chien-Yuan CHEN; Power Digital Card Co., Ltd.

(21) Appl. No.: 11/480,963

(22) Filed: Jul. 6, 2006

(51) Int. Cl. H05K 1/14

(52) U.S. Cl. 361/737

(57) ABSTRACT

The present invention provides a card adaptor device, including a converter card that enables access to data stored therein, structure of which includes disposition of a memory module and a direct memory access controller therein, and functions in coordination with an adaptor device having a MS Pro Duo external form and converter chip to form a configuration conforming to MS Pro Duo electrical structures or functions in coordination with an adaptor device having a MMC/SD series external dimensions to form a configuration suitable as a MMC/SD series interface connector. Hence, a variety of adaptor devices having different interfaces and dimensions enable the card adaptor device to form different types of memory cards having a configuration conforming to MS Pro Duo and MMC/SD interface specifications.

### BACKGROUND OF THE INVENTION

(a) Field of the Invention

The present invention relates to a card adaptor device, and more particularly to a memory card enabling access to data stored therein.

(b) Description of the Prior Art

The upsurge and development of the mobile office and digital video, in addition to the continuous update in the range of use of end consumer electronic products, has brought about an explosive growth in the entire electronic industry in the demand for the new storage media NAND (Not And) Flash. Moreover, light and portable digital cameras, hand-held players (such as: MP3s, PDAs (Personal Digital Assistant), cell-phones), and so on, have already become indispensable products owned by many current consumers, and such products have not only brought the general public or business personnel great convenience and practicality, but have also increased the speculation for tremendous business opportunities stemming from the demand for flash memory cards.

Because a variety of digital products have a continuous demand for inserted memory cards with expanded capacity, thus, the immense business opportunities and profit that stem therefrom are immeasurable. Hence, each manufacturer is striving to become the one that lays down the specifications, thereby controlling the overall market, which has caused sever competition among manufacturers to win over the current present memory card specifications. Taking a broad view of the classification of memory cards, around 10 varieties of memory card specifications have been released on the current market, including the Compact Flash Card (CF card), xD Picture Card (xD card), Secured Digital Card (SD card), Multi Media Card (MMC), Reduced MM card, Smart Media (SM), Memory Stick (including Magic Gate, Memory Stick Pro and Memory Stick Duo derived therefrom) and the new Mini SD card and Trans Flash card (TF card) released by SanDisk.

However, the many different memory card specifications have brought about the problem of which memory card to choose? In fact, the consumer must give prudent consideration to such a question prior to shopping for the aforementioned digital products. Because the specifications and size of each variety of memory card is different, thus, each variety of memory card can only be used with a suitable connector corresponding to that memory card, and possibility of interchangeability between the different memory cards is low. Hence, a consumer often finds that they have purchased a memory card that is incompatible with their digital product, and thus unable to use.

Regarding cost and structure of memory cards, a single memory accounts for approximately 90-98% of the cost of the entire memory card (percentage depending on capacity size), while the other components, such as plastic outer case and conductive metal, account for the remaining 2-10% of the total cost. However, current memory cards of different specifications all employ memory, thus, only size and specifications actually distinguish the different memory cards. In other words, for the sake of differences between the memory cards that only account for 2-10% of the total cost, the consumer is forced to purchase additional cards, with the price of memory cards depending on capacity and specifications. If the consumer owns various digital products of different specifications, then they must purchase a variety of memory cards of different size and specifications, which not only causes inconvenience in use, but also reduces willingness of the consume to purchase and increases the chance of products having old memory cards being left unused.

Hence, if structural configuration of the memory card can be such to not only differentiate between serving as an adaptor device and a data access device (memory module), but also function in coordination with a processor and a conversion chip, then the memory card is able to use a single data access device that not only achieves practical effectiveness, but also reduces purchasing expenditure of the consumer through interchangeability of the adaptor device. Moreover, use ratio of the memory card is improved and reduces the problem of resource wastage because of specification incompatibility or insufficient capacity.

In light of the aforementioned shortcomings in prior art and products, the inventor of the present invention, carried out extensive study and exploration to improve such shortcomings, and ultimately design a new improved structure for a card adaptor device.

### SUMMARY OF THE INVENTION

Accordingly, a primary objective of the present invention is to improve universality of a memory card suitable for use with a variety of digital products.

Another objective of the present invention is to assemble a converter card with data access functionality with various adaptor devices having varied specifications and dimensions to form memory cards of different specifications.

In order to achieve the aforementioned objectives, a card adaptor device of the present invention uses structural configuration of a memory card that differentiates between serving as an adaptor device and a converter card, thereby enabling the converter card with data access functionality and the adaptor device having system switch over functionality to conform to the design of various memory card specifications and dimensions. Moreover, the converter card functions in coordination with an installation able to provide direct memory access (abbreviated to DMA) to form a memory card conforming to MS Pro Duo electrical structures or suitable for use as a MMC/SD series interface connector. The memory card thus assembled from the adaptor device and the converter card t achieves suitability for use in a variety of digital products having different structures.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows a block diagram of a converter card according to the present invention.

FIG. 2 shows a block diagram of the converter card connected to a MS Pro Duo adaptor device according to the present invention.

FIG. 3 shows a block diagram of the converter card connected to a Mini SD adaptor device according to the present invention.

FIG. 4 shows a block diagram of another preferred embodiment according to the present invention.

### DETAILED DESCRIPTION OF THE PREFERRED EMBODIMENTS

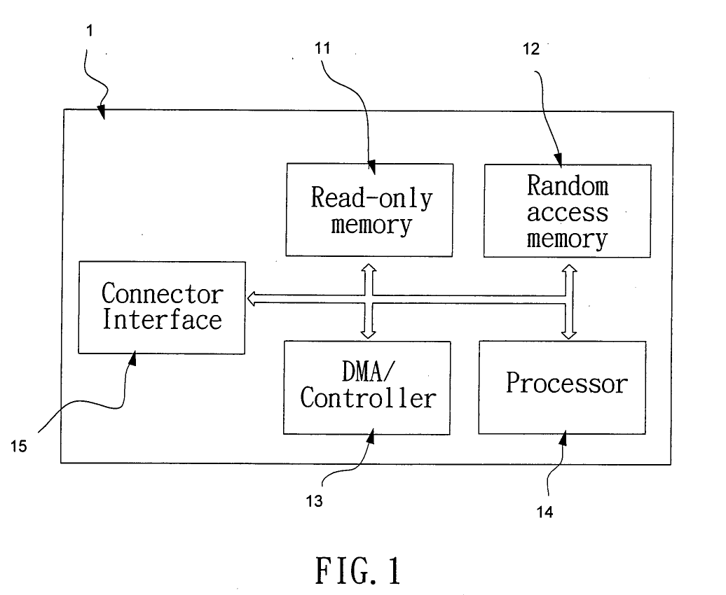

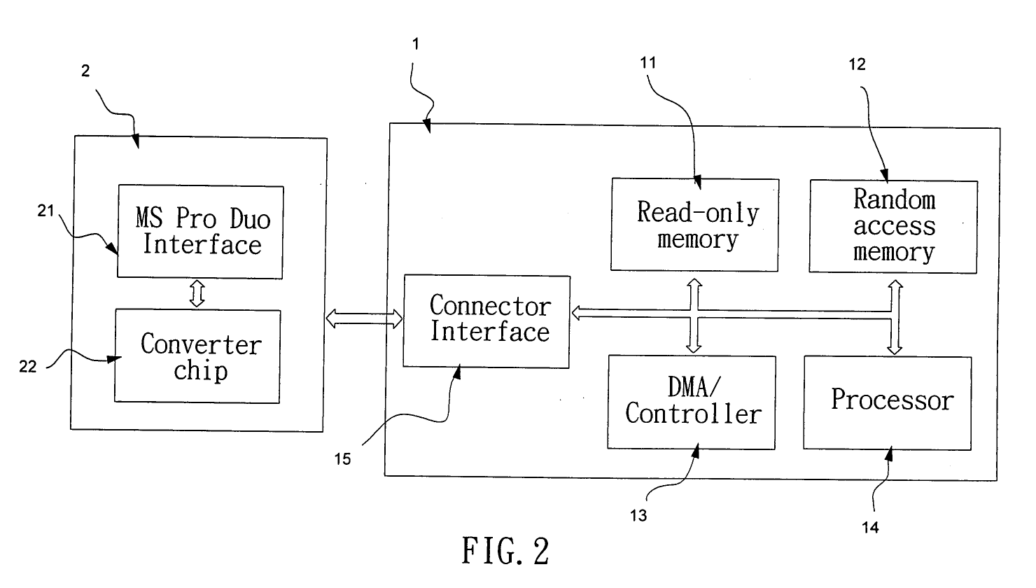

FIG. 1 shows a block diagram of the present invention, and in conjunction with FIGS. 2, 3 and 4, it can be clearly seen that a memory card of the present invention comprises:

A converter card 1 that is a memory module enabling access to data stored therein, and which is structured to comprise a number of passive components, including read-only memory 11, random access memory 12, a controller 13 and a processor 14, which form a circuit link with a connector interface 15. Direct Memory Access (DMA) technology within the controller 13 enables the device to directly read-write to the memory without passing through a processor, thereby reducing load on the processor and increasing data transmission speed.

FIG. 2 shows a block diagram of the converter card 1 connected to a MS Pro Duo adaptor device, wherein exterior configuration of a MS Pro Duo adaptor device 2 includes a MS Pro Duo interface 21 and has size specifications of a MS Pro Duo memory card. A converter chip 22 is built-in within the MS Pro Duo adaptor device 2, and the MS Pro Duo adaptor device 2 is able to contain the aforementioned converter card 1 and form a connection therewith.

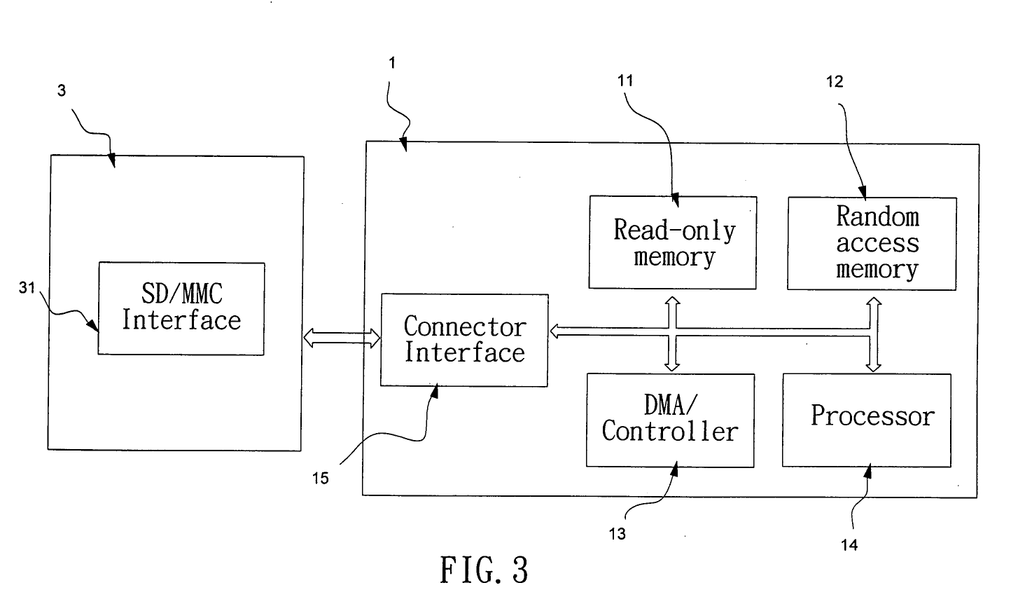

FIG. 3 shows a block diagram of the converter card 1 connected to a Mini SD adaptor device, wherein exterior configuration of a Mini SD adaptor device 3 includes a SD/MMC series interface 31 and has size specifications of a MMC/SD memory card. The Mini SD adaptor device 3 is able to contain the aforementioned converter card 1 and form a connection therewith.

The major characteristic of the present invention is its integration of two memory cards having completely different specifications, more particularly integrating the interface specifications of the Memory Stick series released by the major Japanese home electrical appliance manufacturer SONY and the interface card of the jointly supported SD/MMC series released by Panasonic/Toshiba, thereby providing the memory card of the present invention with the two aforementioned interfaces for use thereof. The present invention primarily separates a memory card of prior art into the converter card 1 and the adapter device, thereby enabling it to use the converter card 1 with data access functionality and form a memory card that uses the MS Pro Duo adapter device 2 or the Mini SD adapter device 3 capable of containing the converter card 1. Hence, different specifications and sizes of the adapter device classify the type of memory card assembled from the converter card 1 and the adapter device 2, 3. If it is desired to assemble a memory card having MS Pro Duo memory card specifications and dimensions, then the adaptor device 2 having MS Pro Duo specifications, dimensions and exterior form is electrically connected to the converter card 1 by means of the connector interface 15 (see FIG. 2), and installation of the controller 13 enabling direct memory access (abbreviated to DMA) within the converter card 1 and the converter chip 22 built-in within the MS Pro Duo adaptor device 2 form a memory card that conforms to MS Pro Duo electrical structures. If it is desired to use the present invention in equipment having a SD/MMC series interface, then the converter card 1 need only be assembled with the SD/MMC adaptor device 3 having a SD/MMC series interface (see FIG. 3). Clearly, the present invention can also be assembled to form a memory card having specifications including Mini SD, Memory Stick, and so on.

Because cost of the memory in the memory card accounts for more than 90% of the total cost of the entire memory card, thus, using the aforementioned configuration whereby the high cost converter card 1 is separated from the low cost adaptor device, interchangeability of the adaptor device transforms the memory card into the required memory card specifications suitable for use in a variety of digital products having different specifications. In other words, specifications of the adaptor device need only be changed and assembled with the converter card 1 to assemble memory cards having a variety of specifications and sizes.

If it is found that there is insufficient memory or capacity is not consistent with requirements, then the converter card 1 need only be replaced with one having a larger memory capacity and connected to existing adaptor device having a variety of sizes, specifications and exterior forms, thereby assembling a memory card having high capacity. Such a configuration not only enables the assembled memory card of the present invention to achieve versatility, but also educes purchasing expenditure of the consume, as well as increasing use ratio of the memory card and reducing the problem of resource wastage due to incompatible specifications or insufficient capacity.

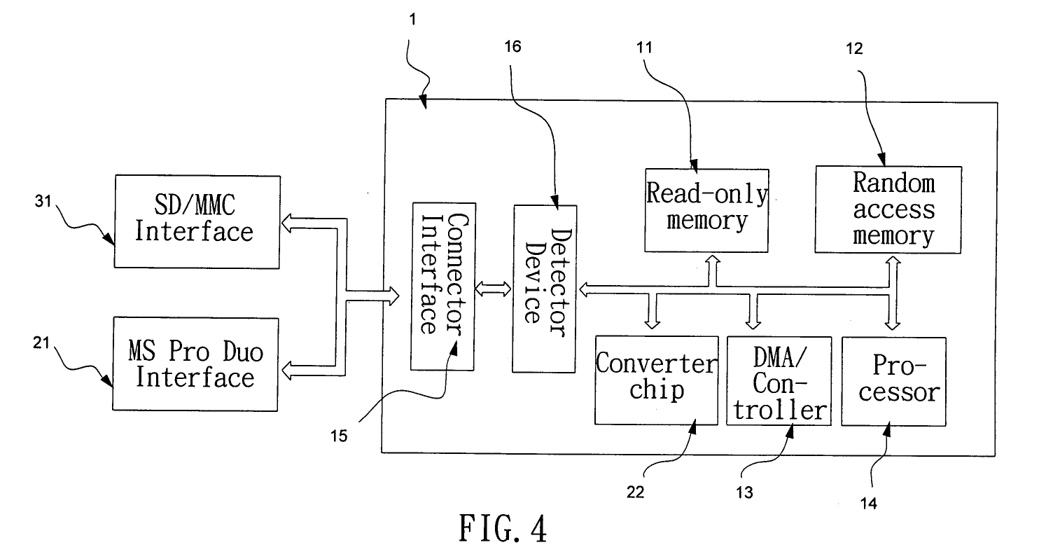

FIG. 4 shows a block diagram of another preferred embodiment of the present invention, wherein the differences between this embodiment and the aforementioned embodiment include the converter chip 22 being built directly within the converter card 1, and use of recognition from a detector device 16 in conjunction with a software program installed in the digital product. When the converter card 1 is connected to a MS Pro Duo interface 21 or a SD/MMC interface 31, a response recognition from the detector device 16 enables the converter card 1 to automatically switch over the system. Because the software program only requires a programmer to program once, the consumer can be provided with free and unlimited access to download and use the software from the Internet or other channels, which distinguishes the present invention from prior art whereby an electronic component/chip is only able to fit one memory card. Hence, the present invention clearly reduces manufacturing cost of the memory card.

In conclusion, the card adaptor device of the present invention clearly remedies the inconvenience caused by the multitude of memory cards presently available using the single converter card 1 connected to an adaptor device having a variety of interfaces and different dimensions to form different types of memory cards suitable for use in corresponding digital products. The present invention provides commercial competitiveness, and contents as disclosed have not been publicly disclosed prior to this application. The present invention clearly complies with essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A card adaptor device, referring to a memory card enabling access to data stored therein, comprising:
a converter card that is a memory module enabling access to data stored therein, structured to comprise a number of passive components, including read-only memory, random access memory, a controller and a processor, which form a circuit link with a connector interface;
an adaptor device that is able to contain the converter card and form a connection therewith, and a connecting interface able to form an electrical connection with external equipment is configured at one end of the adaptor device.

2. The card adaptor device according to claim 1, wherein the connecting interface and external dimensions of the adaptor device conform to MS Pro Duo (Memory Stick Pro Duo) specifications, a converter chip is built-in within the adaptor device, which forms a configuration consistent with a MS Pro Duo electrical structure after the converter card is connected to the adaptor device.

3. The card adaptor device according to claim 1, wherein the connecting interface and external dimensions of the adaptor device conform to Mini SD (Secure Digital) specifications, which forms a configuration consistent with a Mini SD electrical structure after the converter card is connected to the adaptor device.

4. The card adaptor device according to claim 1, wherein the connecting interface and external dimensions of the adaptor device conform to SD/MMC (Multi Media Card) specifications, which forms a configuration consistent with a SD/MMC electrical structure after the converter card is connected to the adaptor device.

5. The card adaptor device according to claim 1, wherein the connecting interface and external dimensions of the adaptor device conform to MS (Memory Stick) specifications, a converter chip is built-in within the adaptor device, which forms a configuration consistent with a MS electrical structure after the converter card is connected to the adaptor device.

6. A card adaptor device, referring to a memory card enabling access to data stored therein, comprising:
a converter card that is a memory module enabling access to data stored therein, structured to comprise a number of passive components, including a converter chip, read-only memory, random access memory, a controller and a processor, which form a circuit link with a connector interface;
an adaptor device that is able to contain the converter card and form a connection therewith, and a connecting interface able to form an electrical connection with external equipment is configured at one end of the adaptor device, thereby forming a configuration conforming to MS Pro Duo and SD/MMC interface specifications.

7. The card adaptor device according to claim 6, wherein a detector device programmed with a software program serves as a MS Pro Duo interface or SD/MMC interface system switch over recognition device.
